(19) United States
(12) Patent Application Publication
(10) Pub. No.: US 2011/0179613 A1
(43) Pub. Date: Jul. 28, 2011

(54) PACKAGE MANUFACTURING METHOD, PIEZOELECTRIC VIBRATOR MANUFACTURING METHOD, OSCILLATOR, ELECTRONIC DEVICE, AND RADIO-CONTROLLED TIMEPIECE

(76) Inventors: Yoichi Funabiki, Chiba-shi (JP); Hitoshi Takeuchi, Chiba-shi (JP)

(21) Appl. No.: 13/011,408

(22) Filed: Jan. 21, 2011

(30) Foreign Application Priority Data
Jan. 25, 2010 (JP) JP2010-013615

(51) Int. Cl. H01L 41/22

(52) U.S. Cl. 29/25.35

(57) ABSTRACT

A package manufacturing method capable of manufacturing a package easily and efficiently. The package manufacturing method includes a jig disposing step of disposing a covering jig covering an outer peripheral portion on one surface of a first board so as to expose a hole forming region through a jig opening formed on the covering jig; and a filling step of filling a filling material constituting at least a part of penetration electrodes into holes. The filling step includes a metal mask disposing step of disposing a metal mask 84 on the covering jig so as to expose the hole forming region through the jig opening and a mask opening of the metal mask; and a main filling step of applying the filling material on the one surface of the first board so as to fill the filling material into the holes using a squeegee. The filling step is repeated in several rounds, and in the metal mask disposing step of a second or later round of the filling step, a metal mask of which the mask opening has a diameter larger than that used in a previous round of the metal mask disposing step is used.

### RELATED APPLICATIONS

This application claims priority under 35 U.S.C. §119 to Japanese Patent Application No. 2010-013615 filed on Jan. 25, 2010, the entire content of which is hereby incorporated by reference.

### BACKGROUND OF THE INVENTION

1. Field of the Invention

The present invention relates to a package manufacturing method, a piezoelectric vibrator manufacturing method, and an oscillator, an electronic device, and a radio-controlled timepiece each having the piezoelectric vibrator.

2. Description of the Related Art

Recently, piezoelectric vibrators utilizing quartz or the like has been used in cellular phones and portable information terminals as the time source, the timing source of a control signal, a reference signal source, and the like. Although there are various piezoelectric vibrators of this type, an SMD (Surface Mount Device)-type piezoelectric vibrator is known as one example thereof. As the piezoelectric vibrator of this type, a three-layered piezoelectric vibrator in which a piezoelectric board having a piezoelectric vibrating reed formed thereon is interposed between a base board and a lid board is known. In this case, the piezoelectric vibrating reed is accommodated in a cavity (sealed space) that is formed between the base board and the lid board.

Moreover, in recent years, instead of the three-layered piezoelectric vibrator, a two-layered piezoelectric vibrator has also been developed. The piezoelectric vibrator of this type has a two-layered structure in which a base board and a lid board are directly bonded, and a piezoelectric vibrating reed is accommodated in a cavity formed between the two boards. The two-layered piezoelectric vibrator is ideally used as it is superior in achieving a thin profile compared with the three-layered structure.

As an example of such a two-layered piezoelectric vibrator, a piezoelectric vibrator in which a conductive member such as a silver paste is filled in penetration holes formed in a base board made of a glass material and baked so as to form penetration electrodes, and piezoelectric vibrating reeds (quartz crystal vibrators) are electrically connected to outer electrodes provided outside the base board is known (for example, see JP-A-2002-124845).

However, in the penetration electrodes formed of the silver paste, since an organic material such as resin in the silver paste is removed by baking and its volume decreases, there is a case where a recess portion is formed on the surfaces of the penetration electrodes, or a hole is opened on the penetration electrodes. The recess portion or hole of the penetration electrodes may decrease the air-tightness of the inside of the cavity or degrade conduction between the piezoelectric vibrating reeds and the outer electrodes.

In recent years, a method of forming penetration electrodes using metal pins made of metallic material has been developed. In this method, first, metal pins are inserted through penetration holes formed in a base board. Then, a glass frit is filled into the penetration holes, and the glass frit is baked so as to integrate the base board and the metal pins to each other. By using the metal pins as the penetration electrodes, stable conduction can be secured.

In the above-described manufacturing method, the filling of the glass frit is performed in accordance with a method described below.

That is, first, a metal mask having openings through which a paste-like glass frit is applied is disposed on the upper surface of a base board. In this way, the outer peripheral portion of the base board is covered with the metal mask, and the central portion of the base board having penetration holes formed thereon is exposed through the openings of the metal mask.

Subsequently, the glass frit is applied onto the upper surface of the base board, and the glass frit is filled into the penetration holes using a squeegee. Here, since the outer peripheral portion of the base board is covered with the metal mask, the glass frit is suppressed from flowing from the upper surface of the base board towards the side surfaces.

After that, the metal mask is removed, and the glass frit is temporarily dried. In this way, binders of an organic material in the glass frit are removed, and the volume of the glass frit decreases, whereby recess portions are formed on the surface of the glass frit. Therefore, in order to fill the glass fit in the recess portions, the above-mentioned operations are repeatedly performed. As a result, it is possible to reliably fill the glass fit in the penetration holes.

However, in the method of filling the glass frit, whenever the filling of the glass frit is repeated, residues of the glass frit are formed on the base board. Here, if the residue of the glass frit is left unremoved, when the metal mask is disposed again on the base board in order to repeat the filling of the glass frit, the residue comes to be positioned between the metal mask and the base board. Thus, a gap is formed between the metal mask and the base board. When the glass frit is filled in such a state where the gap is formed between the metal mask and the base board, the glass frit will enter into the gap, and the glass frit may flow towards the side surfaces of the base board. For this reason, it is necessary to scrape and remove the residue of the glass frit whenever the filling of the glass frit is repeated, and this operation takes much time.

### SUMMARY OF THE INVENTION

The present invention has been made in view of the foregoing, and an object of the present invention is to provide a package manufacturing method capable of manufacturing a package easily and efficiently, a piezoelectric vibrator manufacturing method, and an oscillator, an electronic device, and a radio-controlled timepiece each having the piezoelectric vibrator.

The present invention provides the following means in order to solve the problems.

According to an aspect of the present invention, there is provided a method for manufacturing a package capable of sealing an electronic component in a cavity which is formed between plural boards bonded to each other, the method including: a penetration electrode forming step of forming penetration electrodes penetrating through a first board of the plural boards in a thickness direction thereof so as to electrically connect the inner side of the cavity to the outer side of the package, the penetration electrode forming step including: a hole forming step of forming holes in a hole forming region positioned at a central portion of the first board so as to be opened on at least one surface side of the first board; a jig disposing step of disposing a covering jig covering an outer peripheral portion on the one surface of the first board so as to expose the hole forming region through a jig opening formed on the covering jig; and a filling step of filling a filling material constituting at least a part of the penetration electrodes into the holes, the filling step including: a metal mask disposing step of disposing a metal mask on the covering jig so as to expose the hole forming region through the jig opening and a mask opening formed on the metal mask; a main filling step of applying the filling material on the one surface of the first board so as to fill the filling material into the holes using a squeegee; a metal mask removal step of removing the metal mask; and a drying step of drying the filling material, wherein the filling step is repeated in several rounds, and in the metal mask disposing step of a second or later round of the filling step, a metal mask of which the mask opening has a diameter larger than that used in a previous round of the metal mask disposing step is used.

According to the above aspect of the present invention, in the metal mask disposing step of the second or later round of the filling step, a metal mask of which the mask opening has a diameter larger than that used in the previous round of the metal mask disposing step is used. Therefore, in the metal mask disposing step of the second or later round of the filling step, the metal mask can be disposed so that the residue of the filling material formed in the previous filling step is positioned in the mask opening so as to be surrounded from the outer side in top view. In this way, it is not necessary to remove the residue of the filling material whenever the filling of the filling material is repeated. Moreover, it is possible to manufacture the package easily and efficiently.

Moreover, since the metal mask is disposed on the covering jig during the metal mask disposing step, it is possible to easily increase the diameter of the mask opening every repetition of the filling step while securing the size of the hole forming region of the first board. That is, if the size of the hole forming region of the first board is secured, the size from the hole forming region of the first board to the outer circumference thereof decreases. Therefore, for example, if the size of the hole forming region of the first board is secured in a state where the metal mask is directly placed on the one surface of the first board without the covering jig disposed therebetween, it is difficult to gradually increase the diameter of the mask opening within the range from the hole forming region of the first board to the outer circumference.

When a first board wafer which is cut and fragmented as a plurality of first boards is used as the first board during the penetration electrode forming step, by securing the size of the hole forming region of the first board wafer, it is possible to increase the number of first boards used from one first board wafer.

Since the outer peripheral portion of the first board is covered with the covering jig during the filling step, even when the diameter of the mask opening is increased for every repetition of the filling step, the outer peripheral portion of the first board can be reliably and continuously covered by the covering jig.

The mask opening may have a diameter larger than the jig opening.

In this case, since the mask opening has a diameter larger than the jig opening, when the metal mask is disposed on the covering jig during the metal mask disposing step, the metal mask can be easily positioned so that the hole forming region of the first board is exposed through the jig opening and the mask opening.

During the jig disposing step, the covering jig may be disposed on the one surface of the first board, and a fixing jig may be disposed on the other surface side of the first board so as to interpose the first board in the thickness direction thereof between the covering jig and the fixing jig.

In this case, since the first board is interposed in the thickness direction between the covering jig and the fixing jig during the jig disposing step, the covering jig can be firmly fixed to the first board.

Moreover, since the first board is interposed in the thickness direction between the covering jig and the fixing jig, it is possible to reliably prevent a gap from being formed between the covering jig and the first board. Thus, it is possible to reliably prevent the filling material from coming to be positioned between the covering jig and the first board.

During the hole forming step, the holes may be formed so as to penetrate through the first board in the thickness direction. The penetration electrode forming step may include a rivet member disposing step, after the hole forming step, of inserting core portions of conductive rivet members, which each include the core portion constituting a part of the penetration electrodes and a base portion having a surface on which the core portion is assembled, into the holes from the other surface side of the first board. During the jig disposing step, the first board may be interposed in the thickness direction between the fixing jig and the covering jig while pressing the base portions onto the other surface of the first board with the fixing jig.

In this case, during the jig disposing step, since the base portions are pressed onto the other surface of the first board with the fixing jig, the openings on the other surface side of the holes can be closed by the base portions, and it is possible to prevent the filling material from leaking through the holes towards the other side during the filling step.

Moreover, since the first board is interposed in the thickness direction between the fixing jig and the covering jig with the base portions being pressed onto the other surface of the first board by the fixing jig, simply by disposing the fixing jig, it is possible to realize firm fixing of the fixing jig and suppress leakage of the filling material through the holes. Thus, it is possible to manufacture the package very easily and efficiently.

The penetration electrode forming step may include a jig cleaning step, prior to the jig disposing step, of cleaning the covering jig so as to remove the residue of the filling material on the covering jig.

In this case, since the jig cleaning step is performed prior to the jig disposing step, no gap will be formed between the metal mask and the covering jig, which results from the residue of the filling material.

Moreover, by performing the jig cleaning step prior to the jig disposing step, the covering jig can be used repeatedly.

Furthermore, since the covering jig is cleaned to remove the residue during the jig cleaning step, the removal can be performed easily compared to the case of scraping and removing the residue, for example.

According to another aspect of the present invention, there is provided a piezoelectric vibrator manufacturing method including the steps of performing the package manufacturing method according to the above aspect and disposing a piezoelectric vibrating reed as an electronic component at the inside of the cavity while mounting the piezoelectric vibrating reed on the penetration electrodes.

According to the above aspect of the present invention, since the method uses the package manufacturing method capable of manufacturing a package easily and efficiently, it is possible to provide a low-cost piezoelectric vibrator.

According to a still further aspect of the present invention, there is provided an oscillator in which a piezoelectric vibrator manufactured by the piezoelectric vibrator manufacturing method according to the above aspect of the present invention is electrically connected to an integrated circuit as an oscillating piece.

According to a still further aspect of the present invention, there is provided an electronic device in which a piezoelectric vibrator manufactured by the piezoelectric vibrator manufacturing method according to the above aspect of the present invention is electrically connected to a timer portion.

According to a still further aspect of the present invention, there is provided a radio-controlled timepiece in which a piezoelectric vibrator manufactured by the piezoelectric vibrator manufacturing method according to the above aspect of the present invention is electrically connected to a filter portion.

In the oscillator, electronic device, and radio-controlled timepiece according to the above aspects of the present invention, since they use a low-cost piezoelectric vibrator, they can be manufactured at a low cost.

According to the above aspects of the present invention, it is possible to manufacture a package easily and efficiently.

### BRIEF DESCRIPTION OF THE DRAWINGS

FIG. 1 is a perspective view showing an external appearance of a piezoelectric vibrator according to an embodiment of the present invention.

FIG. 2 shows the internal configuration of the piezoelectric vibrator of FIG. 1 and is a top view showing a state where a lid board of the piezoelectric vibrator is removed.

FIG. 3 is a side sectional view taken along the line A-A in FIG. 2.

FIG. 4 is an exploded perspective view of the piezoelectric vibrator in FIG. 1.

FIG. 5 is a top view of the piezoelectric vibrating reed.

FIG. 6 is a bottom view of the piezoelectric vibrating reed.

FIG. 7 is a sectional view taken along the line B-B in FIG. 5.

FIG. 8 is a flowchart of the piezoelectric vibrator manufacturing method according to an embodiment.

FIG. 9 is an exploded perspective view of a wafer assembly.

FIG. 10 is a diagram illustrating a jig disposing step.

FIG. 11 is a diagram illustrating a glass frit filling step in a first round of a filling step.

FIG. 12 is a diagram illustrating a glass frit drying step in the first round of the filling step.

FIG. 13 is a diagram illustrating a glass fit filling step in the second round of the filling step.

FIG. 14 is a diagram illustrating a glass frit drying step in the second round of the filling step.

FIG. 15 is a diagram illustrating a jig removal step.

FIG. 16 is a diagram illustrating a polishing step.

FIG. 17 is a view showing the configuration of an oscillator according to an embodiment.

FIG. 18 is a view showing the configuration of an electronic device according to an embodiment.

FIG. 19 is a view showing the configuration of a radio-controlled timepiece according to an embodiment.

### DESCRIPTION OF PREFERRED EMBODIMENT

Hereinafter, an embodiment of the present invention will be described with reference to the drawings.

### (Piezoelectric Vibrator)

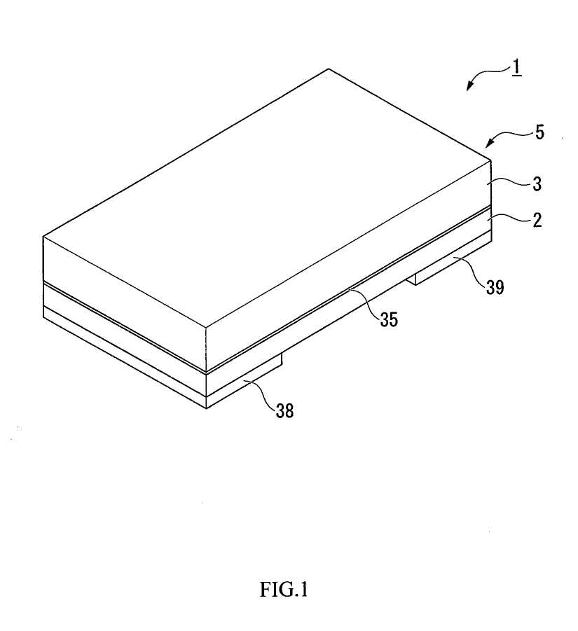

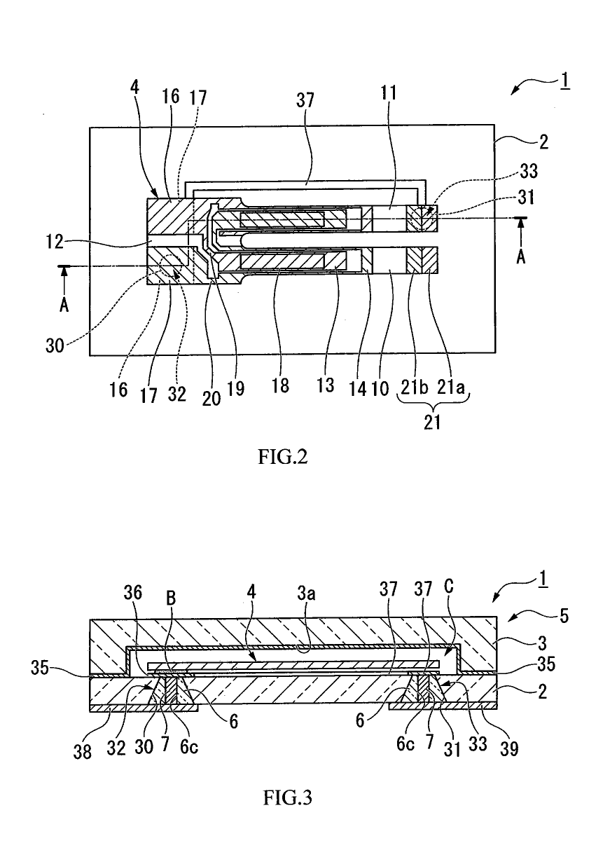

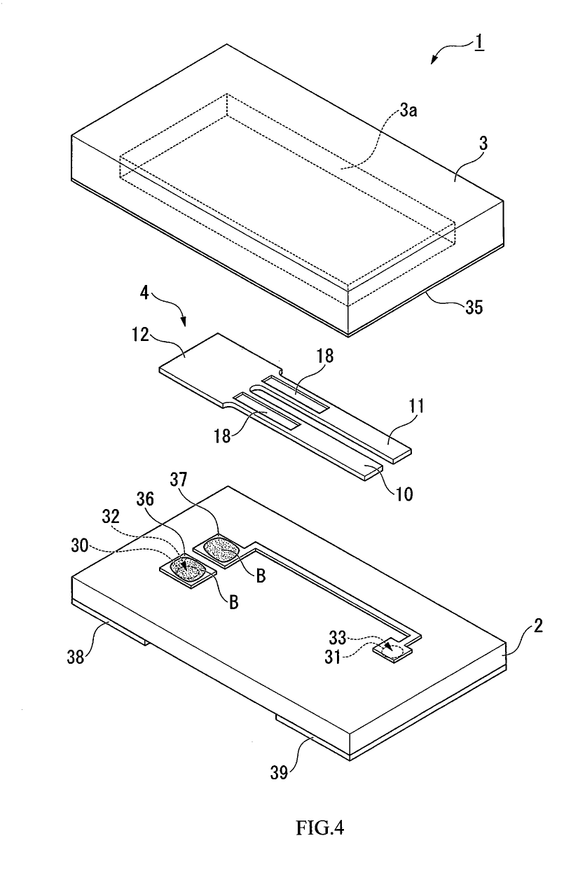

As shown in FIGS. 1 to 4, a piezoelectric vibrator 1 of the present embodiment is an SMD-type piezoelectric vibrator which has a package 5 in which a piezoelectric vibrating reed 4 serving as an electronic component is sealed in a cavity C that is formed between plural boards 2 and 3 bonded to each other. The package 5 is formed in the form of a box laminated in two layers of a base board (first board) 2 and a lid board 3. In FIG. 4, for better understanding of the drawings, illustrations of excitation electrode 15, extraction electrodes 19 and 20, mount electrodes 16 and 17, and weight metal film 21 described later are omitted.

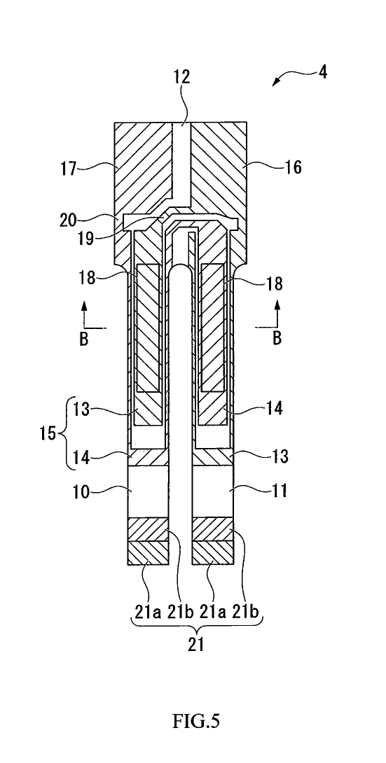

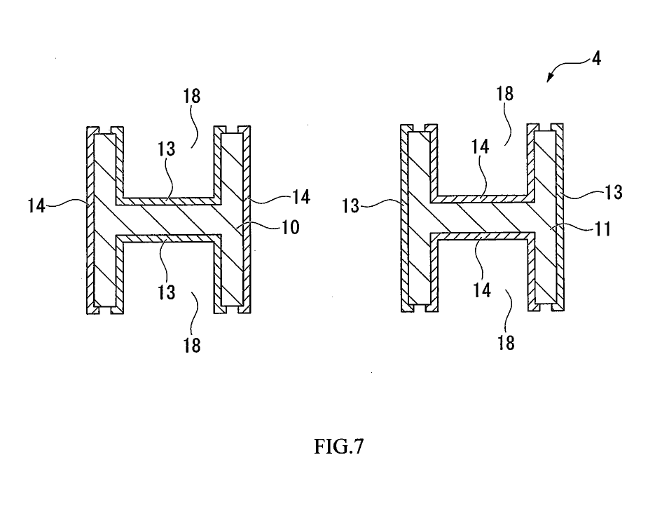

As shown in FIGS. 5 to 7, the piezoelectric vibrating reed 4 is a tuning-fork type vibrating reed which is made of a piezoelectric material such as quartz crystal, lithium tantalate, or lithium niobate and is configured to vibrate when a predetermined voltage is applied thereto.

The piezoelectric vibrating reed 4 includes: a pair of vibrating arms 10 and 11 disposed in parallel to each other; a base portion 12 to which the base end sides of the pair of vibrating arms 10 and 11 are integrally fixed; an excitation electrode 15 which is formed on the outer surfaces of the pair of vibrating arms 10 and 11 so as to allow the pair of vibrating arms 10 and 11 to vibrate and includes first and second excitation electrodes 13 and 14; and mount electrodes 16 and 17 which are electrically connected to the first and second excitation electrodes 13 and 14.

In addition, the piezoelectric vibrating reed 4 according to the present embodiment is provided with groove portions 18 which are formed on both principal surfaces of the pair of vibrating arms 10 and 11 along the longitudinal direction of the vibrating arms 10 and 11. The groove portions 18 are formed so as to extend from the base end sides of the vibrating arms 10 and 11 up to approximately the middle portions thereof.

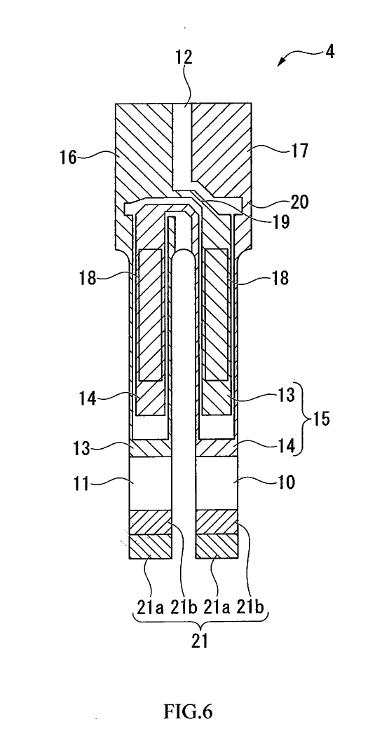

As shown in FIGS. 5 and 6, the excitation electrodes 13 and 14 are formed on the principal surfaces of the pair of vibrating arms 10 and 11. The excitation electrodes 13 and 14 are formed of a single-layer conductive film made of chromium (Cr), for example. The excitation electrode 15 including the first excitation electrode 13 and the second excitation electrode 14 is an electrode that allows the pair of vibrating arms 10 and 11 to vibrate at a predetermined resonance frequency in a direction to move closer to or away from each other and is patterned on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11.

Moreover, the first excitation electrode 13 and the second excitation electrode 14 are electrically connected to the mount electrodes 16 and 17 via the extraction electrodes 19 and 20, respectively, on both principal surfaces of the base portion 12. A voltage is applied to the piezoelectric vibrating reed 4 via the mount electrodes 16 and 17.

The mount electrodes 16 and 17 and the extraction electrodes 19 and 20 are laminated films of chromium (Cr) and gold (Au), which are formed by forming a chromium film having good adhesion with quartz crystal as a base film and then forming a thin gold film on the surface thereof.

Furthermore, the tip ends of the pair of vibrating arms 10 and 11 are coated with a weight metal film 21 for mass adjustment of their own vibration states (tuning the frequency) in a manner such as to vibrate within a predetermined frequency range. The weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal (target) frequency of the device.

The piezoelectric vibrating reed 4 configured in this way is bump-bonded to the inner surface (upper surface) of the base board 2 by bumps B made of gold or the like as shown in FIGS. 3 and 4. More specifically, bump bonding is achieved in a state where each of the pair of mount electrodes 16 and 17 comes into contact with two bumps B, respectively, formed on lead-out electrodes 36 and 37 described later, which are patterned on the inner surface of the base board 2.

The lid board 3 is a transparent insulating board made of a glass material, for example, soda-lime glass, and is formed in a board-like form as shown in FIGS. 1, 3, and 4. A bonding surface side thereof to be bonded to the base board 2 is formed with a rectangular recess portion 3a in which the piezoelectric vibrating reed 4 is accommodated. The recess portion 3a is a recess portion for a cavity serving as the cavity C that accommodates the piezoelectric vibrating reed 4 when the two boards 2 and 3 are superimposed onto each other. The lid board 3 is anodically bonded to the base board 2 in a state where the recess portion 3a faces the base board 2.

Moreover, as shown in FIG. 3, on a surface of the lid board 3 to be bonded to the base board 2, a bonding film 35 for anodic bonding is formed. The bonding film 35 is formed of a conductive material such as aluminum, for example, and is formed by a film-formation method such as sputtering or CVD. The bonding film 35 may be formed over the entire inner surface of the recess portion 3a. In this way, patterning of the bonding material 35 is not necessary, and the manufacturing cost can be reduced.

The lid board 3 is anodically bonded to the base board 2 via the bonding film 35 in a state where the recess portion 3a faces the base board 2.

The base board 2 is a transparent insulating board made of glass material, for example, soda-lime glass, similarly to the lid board 3, and is formed in a board-like form, as shown in FIGS. 1 to 4.

The base board 2 is formed with a pair of penetration holes 30 and 31 penetrating through the base board 2. The penetration holes 30 and 31 of the present embodiment are formed such that one through-hole 30 is positioned at a corresponding position close to the base portion 12 of the mounted piezoelectric vibrating reed 4, and the other through-hole 31 is positioned at a corresponding position close to the tip ends of the vibrating arms 10 and 11.

A pair of penetration electrodes 32 and 33 is formed in the pair of through-holes 30 and 31 so as to bury the through-holes 30 and 31. As shown in FIG. 3, the penetration electrodes 32 and 33 are formed by a cylindrical member 6 and a core portion 7 which are integrally fixed to the penetration holes 30 and 31 by baking. The penetration electrodes 32 and 33 serve to maintain the air-tightness of the inside of the cavity C by completely closing the penetration holes 30 and 31 and achieve an electrical connection between the outer electrodes 38 and 39 described later and the lead-out electrodes 36 and 37.

The cylindrical member 6 is obtained by baking a paste-like glass frit 6a (see FIG. 11) described later. The cylindrical member 6 has a cylindrical shape of which both ends are flat and which has approximately the same thickness as the base board 2. A core portion 7 is disposed at the center of the cylindrical member 6 so as to penetrate through the cylindrical member 6. The cylindrical member 6 and the core portion 7 are baked in a state of being buried in the penetration holes 30 and 31 and are tightly attached to the penetration holes 30 and 31.

The core portion 7 is a conductive cylindrical core material made of metallic material such as stainless steel, silver, or aluminum, and similarly to the cylindrical member 6, has a shape which has flat ends and approximately the same thickness as the base board 2. The core portion 7 is positioned substantially at a central hole 6c of the cylindrical member 6, and is tightly attached to the cylindrical member 6 by the baking of the cylindrical member 6. The electrical connection of the penetration electrodes 32 and 33 is secured by the conductive core portion 7.

Moreover, the pair of lead-out electrodes 36 and 37 are patterned so that one penetration electrode 32 of the pair of penetration electrodes 32 and 33 is electrically connected to one mount electrode 16 of the piezoelectric vibrating reed 4, and the other penetration electrode 33 is electrically connected to the other mount electrode 17 of the piezoelectric vibrating reed 4.

More specifically, one lead-out electrode 36 is formed right above the one penetration electrode 32 to be disposed right below the base portion 12 of the piezoelectric vibrating reed 4. Moreover, the other lead-out electrode 37 is formed to be disposed right above the other penetration electrode 33 after being led out from a position near the one lead-out electrode 36 towards the tip ends of the vibrating arms 10 and 11 along the vibrating arms 10 and 11.

The bumps B are formed on the pair of lead-out electrodes 36 and 37, and the piezoelectric vibrating reed 4 is mounted via the bumps B. In this way, the one mount electrode 16 of the piezoelectric vibrating reed 4 is electrically connected to the one penetration electrode 32 via the one lead-out electrode 36, and the other mount electrode 17 is electrically connected to the other penetration electrode 33 via the other lead-out electrode 37.

Moreover, the outer surface (lower surface) of the base board 2 is formed with the outer electrodes 38 and 39 which are electrically connected to the pair of penetration electrodes 32 and 33, respectively, as shown in FIGS. 1, 3, and 4. That is, one outer electrode 38 is electrically connected to the first excitation electrode 13 of the piezoelectric vibrating reed 4 via the one penetration electrode 32 and the one lead-out electrode 36. In addition, the other outer electrode 39 is electrically connected to the second excitation electrode 14 of the piezoelectric vibrating reed 4 via the other penetration electrode 33 and the other lead-out electrode 37.

When the piezoelectric vibrator 1 configured in this manner is operated, a predetermined drive voltage is applied between the pair of outer electrodes 38 and 39 formed on the base board 2. In this way, a current can be made to flow to the excitation electrode 15 including the first and second excitation electrodes 13 and 14, of the piezoelectric vibrating reed 4, and the pair of vibrating arms 10 and 11 is allowed to vibrate at a predetermined frequency in a direction to move closer to or away from each other. This vibration of the pair of vibrating arms 10 and 11 can be used as the time source, the timing source of a control signal, the reference signal source, and the like.

### (Piezoelectric Vibrator Manufacturing Method)

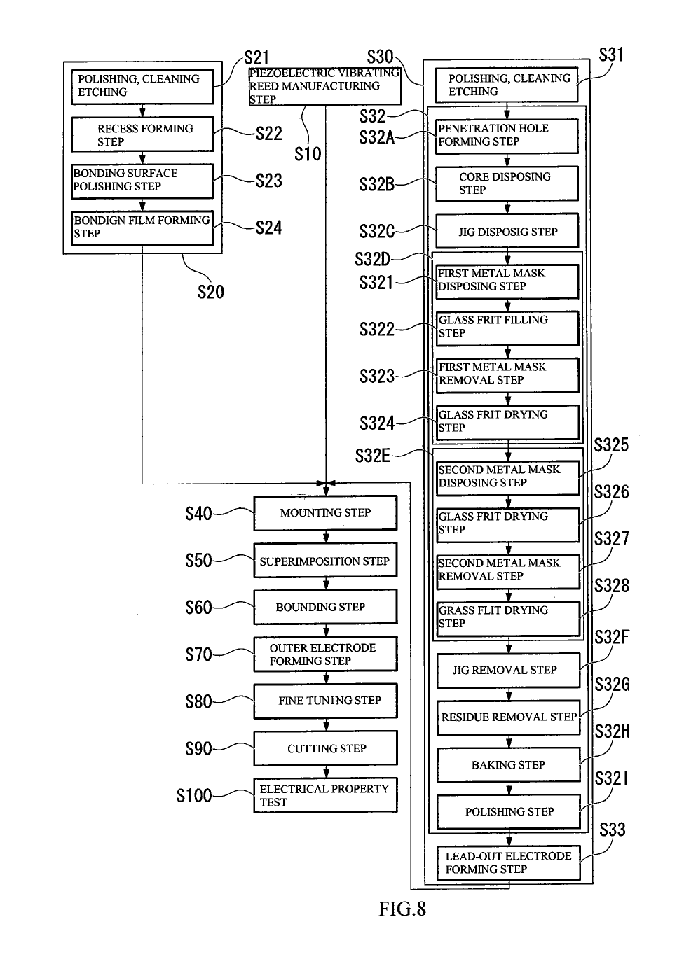

Next, a method for manufacturing the above-described piezoelectric vibrator 1 will be described with reference to the flowchart shown in FIG. 8.

First, a piezoelectric vibrating reed manufacturing step S10 is performed to manufacture the piezoelectric vibrating reed 4 shown in FIGS. 5 to 7. Specifically, first, a rough quartz crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as cleaning, and the wafer is patterned so as to have the outer shape of the piezoelectric vibrating reed 4 by a photolithography technique. Moreover, a metal film is formed and patterned on the wafer, thus forming the excitation electrodes 15, the extraction electrodes 19 and 20, the mount electrodes 16 and 17, and the weight metal film 21. In this way, a plurality of piezoelectric vibrating reeds 4 can be manufactured.

Moreover, after the piezoelectric vibrating reed 4 is manufactured, a step of roughly tuning a resonance frequency is performed. This rough tuning is achieved by irradiating the rough tuning film 21a of the weight metal film 21 with a laser beam to evaporate in part the rough tuning film 21a, thus changing a weight thereof. A fine tuning step of adjusting the resonance frequency more accurately is performed after a mounting step is performed.

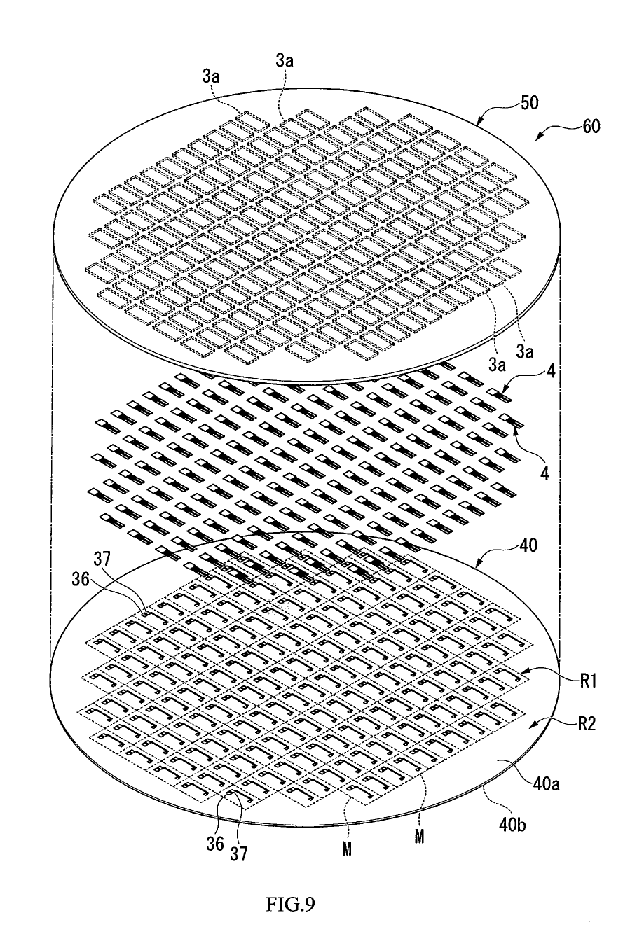

Subsequently, as shown in FIG. 9, at the same or a different time as the above step, a first wafer manufacturing step S20 is performed where the lid board wafer 50 later serving as the lid board 3 (see FIG. 3) is manufactured up to a stage immediately before anodic bonding is achieved. Specifically, a disk-shaped lid board wafer 50 is formed by polishing a soda-lime glass to a predetermined thickness, cleaning the polished glass, and removing the affected uppermost layer by etching or the like (S21). Subsequently, a recess forming step S22 is performed where a plurality of recess portions 3a to be used as a cavity is formed in a matrix form on a bonding surface of the lid board wafer 50 by etching or the like. After that, a bonding surface polishing step S23 is performed where the bonding surface to be bonded to the base board wafer 40 is polished.

Subsequently, a bonding film forming step S24 is performed where a bonding film 35 is formed on the bonding surface to be bonded to the base board wafer 40. The bonding film 35 may be formed over the entire inner surface of the recess portion 3a in addition to the bonding surface to be bonded to the base board wafer 40. In this way, patterning of the bonding film 35 is not necessary, and the manufacturing cost can be reduced. The bonding film 35 can be formed by a film-formation method such as sputtering or CVD. Since the bonding surface polishing step S23 is performed before the bonding film forming step S24, the flatness of the surface of the bonding film 35 can be secured, and stable bonding with the base board wafer 40 can be achieved.

Subsequently, at the same or a different time as the above step, a second wafer manufacturing step S30 is performed where the base board wafer 40 later serving as the base board 2 (see FIG. 3) is manufactured up to a stage immediately before anodic bonding is achieved. First, a disk-shaped base board wafer 40 is formed by polishing a soda-lime glass to a predetermined thickness, cleaning the polished glass, and removing the affected uppermost layer by etching or the like (S31).

Subsequently, as shown in FIG. 3, a penetration electrode forming step S32 is performed where penetration electrodes 32 and 33 are formed so as to penetrate through the base board 2 in the thickness direction thereof so that the inside of the cavity C is electrically connected to the outside of the piezoelectric vibrator 1. The penetration electrode forming step S32 will be described in detail below.

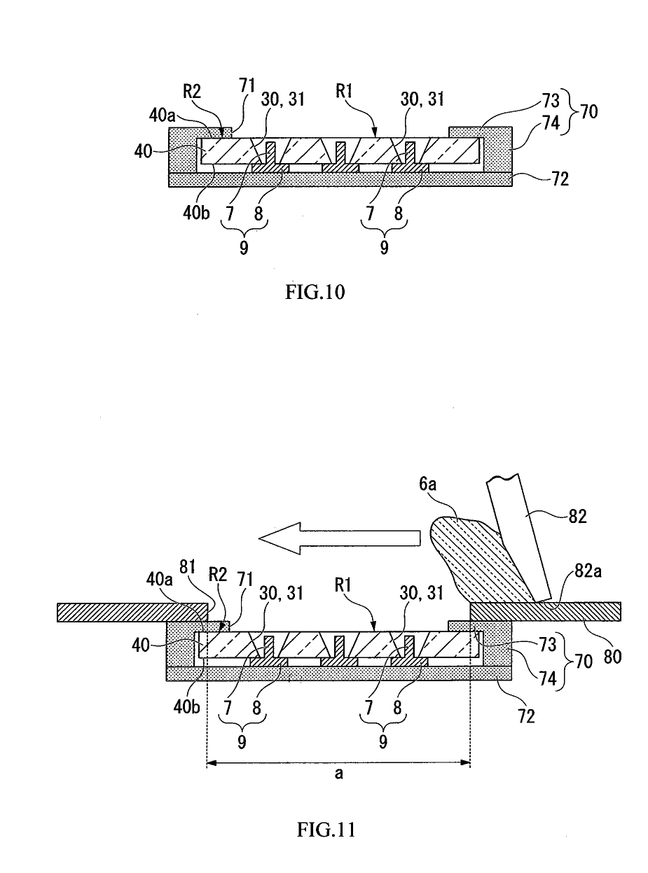

In the penetration electrode forming step S32, first, as shown in FIG. 10, a penetration hole forming step (hole forming step) S32A is performed where penetration holes (holes) 30 and 31 are formed in a hole forming region R1 positioned at the central portion of the base board wafer 40 so as to penetrate through the base board wafer 40 in the thickness direction thereof. At that time, the penetration holes 30 and 31 are formed, for example, by a sand blast method or the like.

In FIG. 10, although the number of penetration holes 30 and 31 is omitted and the sizes thereof and the like are exaggerated for better illustration of the drawing, the number, size, and the like of the penetration holes 30 and 31 are not limited to this. In the illustrated example, although the penetration holes 30 and 31 are formed in a tapered shape, in sectional view, whose diameter gradually decreases from the outer surface (one surface) 40a of the base board wafer 40 towards the inner surface (the other surface) thereof 40b, the penetration holes 30 and 31 may be formed so as to penetrate straight through the base board wafer 40. The outer surface 40a and inner surface 40b of the base board wafer 40 correspond to the outer surface and inner surface of the base board 2, respectively.

After that, a core disposing step S32B is performed where a core portion 7 that constitutes a part of the penetration electrodes 32 and 33 is disposed in the penetration holes 30 and 31. At that time, in the present embodiment, using a conductive rivet member 9 which includes the core portion 7 and a base portion 8 on which the core portion 7 is assembled, the core portion 7 of the rivet member 9 is inserted into the penetration holes 30 and 31 from the inner surface 40b side of the base board wafer 40. In the illustrated example, the tip end of the core portion 7 is positioned in the penetration holes 30 and 31 in a state where the base portion 8 comes into contact with the inner surface 40b of the base board wafer 40, and the tip end does not protrude further out from the outer surface 40a of the base board wafer 40.

Subsequently, a jig disposing step S32C is performed where a covering jig 70 that covers an outer peripheral portion R2 on the outer surface 40a of the base board wafer 40 is disposed so as to expose the hole forming region R1 through a jig opening 71 formed on the covering jig 70. At that time, in the present embodiment, the covering jig 70 is disposed on the outer surface 40a of the base board wafer 40, and a fixing jig 72 is disposed on the inner surface 40b side of the base board wafer 40 so as to interpose the base board wafer 40 in the thickness direction thereof between the covering jig 70 and the fixing jig 72.

In the present embodiment, the covering jig 70 has a cylindrical shape with a low height and an apex, the jig opening 71 is formed at the central portion of an apex wall 73 of the covering jig 70, and the inner diameter of the circumferential wall 74 of the covering jig 70 is larger than the outer diameter of the base board wafer 40. The thickness of the apex wall 73 is, for example, 50 μm to 100 μm. The fixing jig 72 is configured as a planar member which has the same top-view shape and size as those of the apex wall 73 of the covering jig 70. The fixing jig 72 is detachably fixed to the lower end of the circumferential wall 74 by a fixing member (not shown) and closes the lower end of the circumferential wall 74. The covering jig 70 and the fixing jig 72 are formed of a metallic material, for example, and preferably aluminum, iron, or the like.

In the jig disposing step S32C, the base board wafer 40 is interposed in the thickness direction between the fixing jig 72 and the apex wall 73 of the covering jig 70 while pressing the base portion 8 of the rivet member 9 onto the inner surface 40b of the base board wafer 40 with the fixing jig 72.

Subsequently, as shown in FIG. 11, a filling step S32D is performed where a glass frit (filling material) 6a that constitutes at least a part of the penetration electrodes 32 and 33 is filled into the penetration holes 30 and 31. The filling step S32D may be performed in a depressurized atmosphere by putting the base board wafer 40 into a vacuum chamber (not shown).

In the filling step S32D, first, a first metal mask disposing step S321 is performed where a first metal mask 80 is placed on the covering jig 70, and the hole forming region R1 of the base board wafer 40 is exposed through the jig opening 71 and a mask opening 81 formed on the metal mask 80. At that time, the first metal mask 80 and the covering jig 70 are brought into close contact with each other.

Here, in the present embodiment, the first metal mask 80 is a planar member which has a thickness of about 50 μm, for example and is formed of stainless steel so as to cover the entire outer surface 40a of the base board wafer 40. The mask opening 81 of the first metal mask 80 is formed at the central portion of the first metal mask 80 and has a diameter larger than the jig opening 71.

Subsequently, as shown in FIG. 11, a glass frit filling step (main filling step) S322 is performed where a glass frit 6a is applied onto the outer surface 40a of the base board wafer 40 so as to fill the glass frit 6a into the penetration holes 30 and 31 using a squeegee 82. Here, the squeegee 82 is formed of a soft member having flexibility such as urethane rubber and has a width larger than the opening width of the mask opening 81.

In this step, first, the glass frit 6a is applied onto the hole forming region R1 of the base board wafer 40. In the present embodiment, the glass frit 6a is disposed on the outer surface 40a side (in the illustrated example, on the first metal mask 80) of the base board wafer 40, and the squeegee 82 is moved on the mask opening 81 while pressing the squeegee 82 onto the first metal mask 80. At that time, the squeegee 82 is moved in a state of crossing the mask opening 81 in a direction crossing the moving direction, whereby a tip end 82a of the squeegee 82 bends towards the inner sides of the mask opening 81 and the jig opening 71. Therefore, the glass frit 6a extends in the hole forming region R1 while being pressed towards the base board wafer 40 by the squeegee 82. In this way, the glass frit 6a is applied onto the hole forming region R1 of the base board wafer 40 through the mask opening 81 and the jig opening 71 and filled into the penetration holes 30 and 31.

After that, the redundant glass frit 6a applied onto the outer surface 40a of the hole forming region R1 is removed. In the present embodiment, similarly to the application of the glass frit 6a, the squeegee 82 is moved on the mask opening 81 while pressing the squeegee 82 onto the first metal mask 80 so that the tip end 82a of the squeegee 82 bends towards the inner sides of the mask opening 81 and the jig opening 71. At that time, the squeegee 82 is pressed so that the tip end 82a of the squeegee 82 comes into contact with the outer surface 40a of the hole forming region R1 of the base board wafer 40, whereby the glass frit 6a on the outer surface 40a of the hole forming region R1 can be scraped and removed by the squeegee 82. In this way, it is possible to remove the redundant glass frit 6a while filling the glass frit 6a into the penetration holes 30 and 31.

In this way, the glass frit filling step S322 ends. The kind of the squeegee 82 being used and the direction of moving the squeegee 82 may be different from the application to the removal of the glass frit 6a. Moreover, the glass frit filling step S322 is not limited to the above-described method.

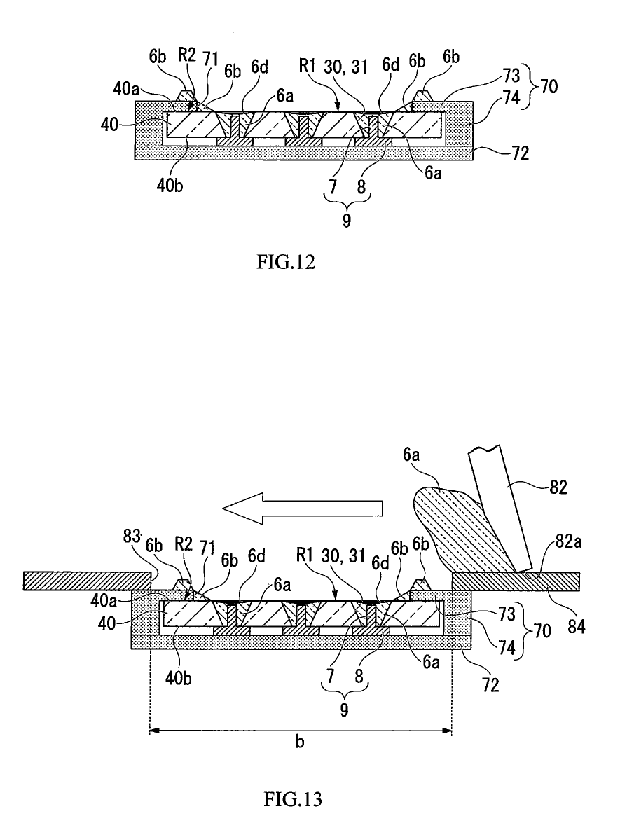

Here, as shown in FIG. 12, on the outer surface 40a of the base board wafer 40 and the covering jig 70, there are portions which rarely come into contact with the bent squeegee 82 (for example, the corners formed on the side surfaces of the jig opening 71 and the outer surface 40a of the base board wafer 40). The glass frit 6a in these portions cannot be removed completely by the squeegee 82 and will remain as a glass frit residue 6b.

Subsequently, after a first metal mask removal step S323 is performed so as to remove the first metal mask 80, a glass frit drying step (drying step) S324 is performed so as to dry the glass frit 6a. In the glass frit drying step S324, for example, each of the base board wafers 40 interposed between the covering jig 70 and the fixing jig 72 may be put into a drying furnace.

In this way, the glass frit 6a filled into the penetration holes 30 and 31 and the glass frit residue 6b on the outer surface 40a of the base board wafer 40 and the covering jig 70 are dried, and the filling step S32D ends.

Here, as shown in FIG. 12, when the glass frit drying step S324 is performed, binders of an organic material in the glass frit 6a are removed, whereby recess portions 6d are formed on the surface of the glass frit 6a filled into the penetration holes 30 and 31. Therefore, as shown in FIG. 8, in order to fill the glass frit 6a into the recess portions 6d, the filling step is repeatedly performed in several rounds (S32D, S32E). In a metal mask disposing step S325 of the second or later round of the filling step S32E, a metal mask 84 of which the mask opening 83 has a diameter larger than that used in the previous metal mask disposing step S321 is used.

In this embodiment, the filling step is repeated in two rounds (S32D, S32E). In the second round of the filling step S32E, description of the same portions as those of the first round of the filling step S32D will be omitted, and only the differences will be described.

In the second round of the filling step S32E, as shown in FIG. 13, during a second metal mask disposing step S325, a second metal mask 84 of which the mask opening has an inner diameter larger than the inner diameter a of the mask opening 81 of the first metal mask 80 used in the first metal mask disposing step S321 of the first round of the filling step S32D is used. By doing so, in the second metal mask disposing step S325, the second metal mask 84 can be disposed so that the glass frit residues 6b formed in the first round of the filling step S32D are positioned in the mask opening 83 so as to be surrounded from the outer side in top view.

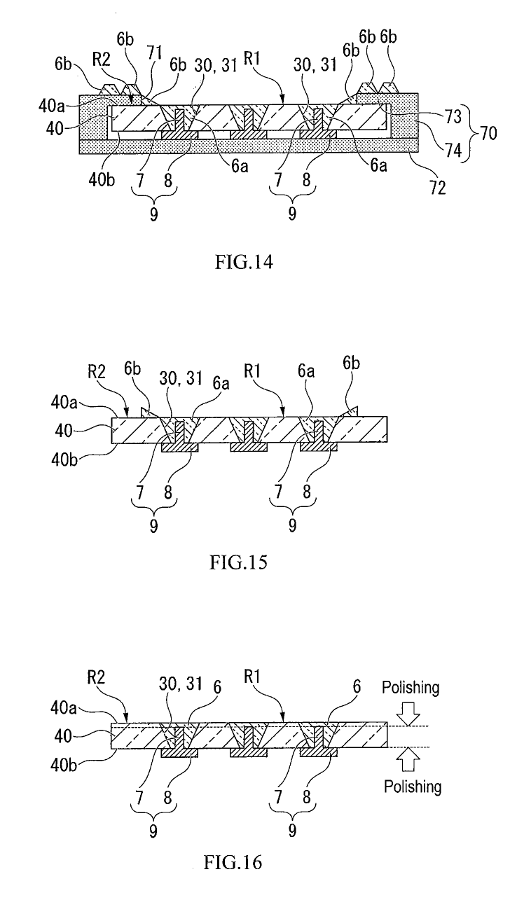

The glass frit 6a is filled into the recess portions 6d formed on the surface of the glass frit 6a in the penetration holes 30 and 31 using the squeegee 82 in a glass frit filling step S326. Thereafter, as shown in FIG. 14, the second metal mask 84 is removed in a second metal mask removal step S327, and then, the glass frit 6a is dried in a glass frit drying step S328.

In this way, the second round of the filling step S32E ends. If the recess portions 6d are still formed on the glass frit 6a in the penetration holes 30 and 31 even after the second round of the filling step S32E, the filling step may be repeated once more.

Subsequently, as shown in FIG. 15, a jig removal step S32F is performed so as to remove the covering jig 70 and the fixing jig 72 from the base board wafer 40. Thereafter, a residue removal step S32G is performed so as to scrape the glass frit residues 6b on the outer surface 40a of the base board wafer 40, and then, a baking step S32H is performed so as to bake and cure the glass frit 6a filled into the penetration holes 30 and 31. In the baking step S32H, the glass frit 6a filled into the penetration holes 30 and 31 is baked to a predetermined temperature and cured. By performing the baking step S32H, as shown in FIG. 16, the glass frit 6a is tightly attached to the penetration holes 30 and 31 and the core portions 7 to form cylindrical members 6, whereby the penetration electrodes 32 and 33 are formed.

Finally, a polishing step S32I is performed so as to polish the base board wafer 40 and the base portions 8 of the rivet members 9. Specifically, the outer surface 40a of the base board wafer 40 is polished until the tip ends of the core portions 7 are exposed, and the base portions 8 of the rivet member 9 are polished and removed. As a result, as shown in FIG. 3, it is possible to obtain a plurality of penetration electrodes 32 and 33 in which the cylindrical members 6 are integrally fixed to the core portions 7.

In this way, the penetration electrode forming step S32 ends.

After that, as shown in FIG. 9, a lead-out electrode forming step S33 is performed where a plurality of lead-out electrodes 36 and 37 is formed so as to be electrically connected to the penetration electrodes, respectively. Then, spire-shaped bumps made of gold are formed on the lead-out electrodes 36 and 37. In FIG. 9, illustrations of the bumps are omitted for better illustration of the drawing. The second wafer manufacturing step S30 ends at this point in time.

Subsequently, a mounting step S40 is performed where the piezoelectric vibrating reeds 4 are bonded to the lead-out electrodes 36 and 37 of the base board wafer 40 via bumps B. Thereafter a superimposition step S50 is performed where the lid board wafer 50 is superimposed onto the base board wafer 40.

After the superimposition step S50 is performed, a bonding step S60 is performed where the two superimposed wafers are inserted into an anodic bonding machine (not shown) to achieve anodic bonding under a predetermined temperature and atmosphere with application of a predetermined voltage to form a wafer assembly 60. When the anodic bonding is performed, since the penetration holes 30 and 31 formed on the base board wafer 40 are completely closed by the penetration electrodes 32 and 33, the airtightness in the cavity C will not be impaired by the penetration holes 30 and 31. In addition, since the cylindrical members 6 and the core portions 7 are integrally fixed by the baking, and they are tightly attached to the penetration holes 30 and 31, it is possible to reliably maintain the airtightness in the cavity C.

After the above-described anodic bonding is completed, an outer electrode forming step S70 is performed where a conductive material is patterned onto the outer surface 40a of the base board wafer 40 so as to form a plurality of pairs of outer electrodes 38 and 39 (see FIG. 3) which is electrically connected to the pair of penetration electrodes 32 and 33.

Subsequently, a fine tuning step is performed on the wafer assembly 60 where the frequencies of the individual piezoelectric vibrators 1 sealed in the cavities C are tuned finely to fall within a predetermined range (S80).

After the fine tuning of the frequency is completed, a cutting step is performed where the bonded wafer assembly 60 is cut along the cutting line M to obtain small fragments (S90).

Subsequently, an inner electrical property test (S100) is conducted, whereby the manufacturing of the piezoelectric vibrator 1 ends.

As described above, according to the piezoelectric vibrator manufacturing method of the present embodiment, in the metal mask disposing step S325 of the second or later round of the filling step S32E, the metal mask 84 of which the mask opening 83 has a diameter larger than that used in the previous metal mask disposing step S321 is used. Therefore, in the second metal mask disposing step S325 of the second or later round of the filling step S32E, the second metal mask 84 can be disposed so that the residue 6b of the glass frit 6a formed in the previous filling step S32D are positioned in the mask opening 83 so as to be surrounded from the outer side in top view. In this way, it is not necessary to remove the residue 6b of the glass frit 6a whenever the filling of the glass frit 6a is repeated. Moreover, it is possible to manufacture the piezoelectric vibrator 1 (package 5) easily and efficiently and achieve cost reduction of the piezoelectric vibrator 1 (package 5).

Moreover, since the metal masks 80 and 84 are disposed on the covering jig 70 during the metal mask disposing steps S321 and S325, it is possible to easily increase the diameters of the mask openings 81 and 83 for every repetition of the filling steps S32D and S32E while securing the size of the hole forming region R1 of the base board wafer 40. That is, if the size of the hole forming region R1 of the base board wafer 40 is secured, the size from the hole forming region R1 of the base board wafer 40 to the outer circumference thereof decreases. Therefore, for example, if the size of the hole forming region R1 of the base board wafer 40 is secured in a state where the metal masks 80 and 84 are directly placed on the outer surface 40a of the base board wafer 40 without the covering jig 70 disposed therebetween, it is difficult to gradually increase the diameters of the mask openings 81 and 83 within the range from the hole forming region R1 of the base board wafer 40 to the outer circumference.

In the case of the present embodiment in which the piezoelectric vibrators 1 (packages 5) are manufactured using the base board wafer 40 which is cut and fragmented as a plurality of base boards 2, by securing the size of the hole forming region R1 of the base board wafer 40, it is possible to increase the number of base boards 2 used from one base board wafer 40.

Since the outer peripheral portion R2 of the base board wafer 40 is covered with the covering jig 70 during the filling steps S32D and S32E, even when the diameters of the mask openings 81 and 83 are increased for every repetition of the filling steps S32D and S32E, the outer peripheral portion R2 of the base board wafer 40 can be continuously and reliably covered by the covering jig 70.

Moreover, since the mask openings 81 and 83 have a diameter larger than the jig opening 71, when the metal masks 80 and 84 are disposed on the covering jig 70 during the metal mask disposing steps S321 and S325, the metal masks 80 and 84 can be easily positioned so that the hole forming region R1 of the base board wafer 40 is exposed through the jig opening 71 and the mask openings 81 and 83.

Since the base board wafer 40 is interposed in the thickness direction between the covering jig 70 and the fixing jig 72 during the jig disposing step S32C, the covering jig 70 can be firmly fixed to the base board wafer 40.

Moreover, since the base board wafer 40 is interposed in the thickness direction between the covering jig 70 and the fixing jig 72, it is possible to reliably prevent a gap from being formed between the covering jig 70 and the base board wafer 40. Thus, it is possible to reliably prevent the glass frit 6a from coming to be positioned between the covering jig 70 and the base board wafer 40.

### (Oscillator)

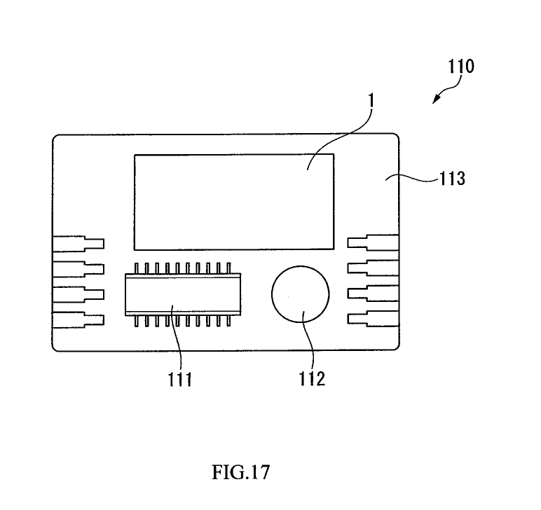

Next, an oscillator according to an embodiment of the present invention will be described with reference to FIG. 17.

As shown in FIG. 17, an oscillator 110 of the present embodiment is one in which the piezoelectric vibrator 1 is configured as an oscillating piece that is electrically connected to an integrated circuit 111. The oscillator 110 includes a board 113 on which an electronic component 112 such as a capacitor is mounted. The integrated circuit 111 for the oscillator is mounted on the board 113, and the piezoelectric vibrating reed 4 of the piezoelectric vibrator 1 is mounted in the vicinity of the integrated circuit 111. The electronic component 112, the integrated circuit 111, and the piezoelectric vibrator 1 are electrically connected by a wiring pattern which is not shown. It should be noted that these components are molded by resin which is not shown.

In the oscillator 110 configured in this manner, the piezoelectric vibrating reed 4 in the piezoelectric vibrator 1 vibrates when a voltage is applied to the piezoelectric vibrator 1. This vibration is converted to an electrical signal by the piezoelectric properties of the piezoelectric vibrating reed 4 and is then input to the integrated circuit 111 as an electrical signal. The input electrical signal is subjected to various kinds of processing by the integrated circuit 111 and is then output as a frequency signal. In this way, the piezoelectric vibrator 1 functions as an oscillating piece.

By selectively setting the configuration of the integrated circuit 111, for example, an RTC (Real Time Clock) module, according to the demand, it is possible to add a function of controlling the date or time for operating the device or an external device or providing the time or calendar in addition to a single-function oscillator for a timepiece.

According to the oscillator 110 of the present embodiment, since the oscillator includes the low-cost piezoelectric vibrator 1, it is possible to achieve cost reduction of the oscillator 110 itself.

### (Electronic Device)

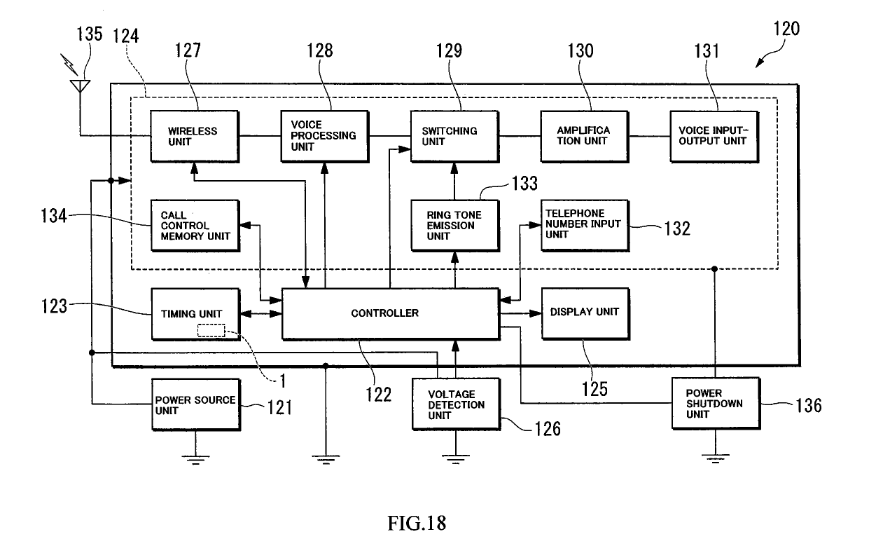

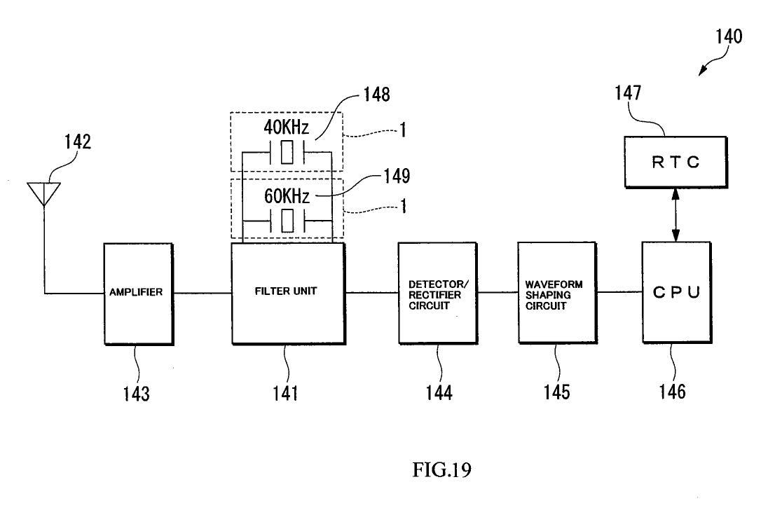

Next, an electronic device according to an embodiment of the present invention will be described with reference to FIG. 18. The present embodiment will be described by way of an example of a portable information device 120 having the piezoelectric vibrator 1 as an example of the electronic device.

First, the portable information device 120 of the present embodiment is represented, for example, by a cellular phone and is one that develops and improves a wristwatch of the related art. The portable information device 120 looks like a wristwatch in external appearance and is provided with a liquid crystal display at a portion corresponding to the dial pad and is capable of displaying the current time or the like on the screen. When the portable information device 120 is used as a communication tool, the user removes it from their wrist and performs communication as with a cellular phone of the related art using the internal speaker and microphone on the inner side of its strap. However, the portable information device 120 is remarkably small and light compared with the cellular phone of the related art.

Next, the configuration of the portable information device 120 of the present embodiment will be described. As shown in FIG. 18, the portable information device 120 includes the piezoelectric vibrator 1 and a power supply portion 121 for supplying power. The power supply portion 121 is formed, for example, of a lithium secondary battery. The power supply portion 121 is connected in parallel to a control portion 122 that performs various kinds of control, a timer portion 123 that counts the time or the like, a communication portion 124 that performs communication with the outside, a display portion 125 that displays various kinds of information, and a voltage detection portion 126 that detects voltages at the respective function portions. The power supply portion 121 supplies power to the respective function portions.

The control portion 122 controls the respective function portions so as to control the operation of the overall system, such as operations to transmit and receive audio data and operations to count and display the current time. The control portion 122 includes a ROM in which a program is written in advance, a CPU that reads out and runs the program written to the ROM, a RAM used as a work area of the CPU, and the like.

The timer portion 123 includes an integrated circuit enclosing an oscillation circuit, a register circuit, a counter circuit, and an interface circuit, and the like as well as the piezoelectric vibrator 1. When a voltage is applied to the piezoelectric vibrator 1, the piezoelectric vibrating reed 4 vibrates, and this vibration is converted to an electrical signal by the piezoelectric properties of the quartz and is input to the oscillation circuit as the electrical signal. The output of the oscillation circuit is converted to a digital form and counted by the register circuit and the counter circuit. Signals are transmitted and received to and from the control portion 122 via the interface circuit, and the current time and the current date or the calendar information or the like are displayed on the display portion 125.

The communication portion 124 is provided with the same functions as those of the cellular phone of the related art, and includes a wireless portion 127, an audio processing portion 128, a switching portion 129, an amplifier portion 130, an audio input/output portion 131, a telephone number input portion 132, a ring tone generation portion 133, and a call control memory portion 134.

The wireless portion 127 carries out transmission and reception of various kinds of data, such as audio data, with the base station via an antenna 135. The audio processing portion 128 encodes and decodes an audio signal input therein from the wireless portion 127 or the amplifier portion 130. The amplifier portion 130 amplifies a signal input therein from the audio processing portion 128 or the audio input/output portion 131 to a predetermined level. The audio input/output portion 131 is formed of a speaker and a microphone and the like, and makes a ring tone and an incoming audio louder, as well as collecting audio.

The ring tone generation portion 133 generates a ring tone in response to a call from the base station. The switching portion 129 switches the amplifier portion 130 normally connected to the audio processing portion 128 to the ring tone generation portion 133 only when a call arrives, so that the ring tone generated in the ring tone generation portion 133 is output to the audio input/output portion 131 via the amplifier portion 130.

The call control memory portion 134 stores a program relating to incoming and outgoing call control for communication. The telephone number input portion 132 includes, for example, numeric keys from 0 to 9 and other keys and the user inputs the telephone number of the communication party by depressing these numeric keys.

The voltage detection portion 126 detects a voltage drop when a voltage being applied to each function portion, such as the control portion 122, by the power supply portion 121 drops below the predetermined value, and notifies the control portion 122 of the detection. The predetermined voltage value referred to herein is a value pre-set as the lowest voltage necessary to operate the communication portion 124 in a stable manner, and for example, is about 3 V. Upon receipt of a notification of a voltage drop from the voltage detection portion 126, the control portion 122 disables the operation of the wireless portion 127, the audio processing portion 128, the switching portion 129, and the ring tone generation portion 133. In particular, it is essential to stop the operation of the wireless portion 127 that consumes a large amount of power. Furthermore, a message informing that the communication portion 124 is unavailable due to insufficient battery power is displayed on the display portion 125.

More specifically, it is possible to disable the operation of the communication portion 124 and display the notification message on the display portion 125 by the voltage detection portion 126 and the control portion 122. This message may be displayed as a character message, or as a more intuitive indication, which may be displayed by putting a cross mark on the telephone icon displayed at the top of the display screen of the display portion 125.

By providing a power shutdown portion 136 capable of selectively shutting down the power supply to portions involved with the function of the communication portion 124, it is possible to stop the function of the communication portion 124 in a more reliable manner.

According to the portable information device 120 of the present embodiment, since the portable information device includes the low-cost piezoelectric vibrator 1, it is possible to achieve cost reduction of the portable information device itself.

### (Radio-Controlled Timepiece)

Next, a radio-controlled timepiece according to an embodiment of the present invention will be described with reference to FIG. 19.

As shown in FIG. 19, a radio-controlled timepiece 140 of the present embodiment includes the piezoelectric vibrators 1 electrically connected to a filter portion 141. The radio-controlled timepiece 140 is a timepiece provided with the function of displaying the correct time by automatically correcting the time upon receipt of a standard radio wave including the clock information.

In Japan, there are transmission centers (transmission stations) that transmit standard radio waves in Fukushima Prefecture (40 kHz) and Saga Prefecture (60 kHz), and each center transmits standard radio waves. Wave as long as 40 kHz or 60 kHz have a nature to propagate along the land surface and a nature to propagate while reflecting between the ionospheric layer and the land surface, and therefore have a propagation range wide enough to cover all of Japan using the two transmission centers.

Hereinafter, the functional configuration of the radio-controlled timepiece 140 will be described in detail.

An antenna 142 receives the long standard radio waves at 40 kHz or 60 kHz. The long standard radio wave is made up of time information called a time code which is modulated by the AM modulation scheme and carried on a carrier wave of 40 kHz or 60 kHz. The long standard wave received are amplified by an amplifier 143 and filtered and synchronized by the filter portion 141 having a plurality of piezoelectric vibrators 1.

In the present embodiment, the piezoelectric vibrators 1 include quartz vibrator portions 148 and 149 having resonance frequencies at 40 kHz and 60 kHz which are the same as the carrier frequency.

Furthermore, the filtered signal at the predetermined frequency is detected and demodulated by a detection and rectification circuit 144.

Subsequently, the time code is extracted by a waveform shaping circuit 145 and counted by the CPU 146. The CPU 146 reads out information about the current year, the total number of days, a day of the week, and the time. The read information is reflected on the RTC 147 and the precise time information is displayed.

Because the carrier wave is 40 kHz or 60 kHz, a vibrator having the tuning-fork structure described above is suitable for the quartz vibrator portions 148 and 149.

Although the above description has been given of an example in Japan, the frequency of the long standard waves is different overseas. For example, standard waves of 77.5 kHz are used in Germany. When the radio-controlled timepiece 140 which is also operable overseas is incorporated into a portable device, the piezoelectric vibrator 1 set at a frequency different from the frequencies used in Japan is required.

According to the radio-controlled timepiece 140 of the present embodiment, since the radio-controlled timepiece includes the low-cost piezoelectric vibrator 1, it is possible to achieve cost reductions of the radio-controlled timepiece itself.

It should be noted that the technical scope of the present invention is not limited to the embodiments above, and the present invention can be modified in various ways without departing from the spirit of the present invention.

For example, the penetration electrode forming step S32 may include a jig cleaning step of cleaning the covering jig 70 so as to remove the residue 6b of the glass frit 6a on the covering jig 70 prior to the jig disposing step S32C. In this step, for example, the covering jig 70 is dipped into an organic solvent and subjected to ultrasonic cleaning, whereby the residue 6b of the glass frit 6a is removed.

In this case, since the jig cleaning step is performed prior to the jig disposing step S32C, no gap will be formed between the metal masks 80 and 84 and the covering jig 70, which result from the residue 6b of the glass frit 6a.

Moreover, by performing the jig cleaning step prior to the jig disposing step S32C, the covering jig 70 can be used repeatedly.

Furthermore, since the covering jig 70 is cleaned to remove the residue 6b during the jig cleaning step, the removal can be performed easily compared to the case of scraping and removing the residue 6b, for example.

In the above-described embodiment, although the mask opening 81 of the first metal mask 80 has a diameter larger than the jig opening 71, the present invention is not limited to this. For example, the mask opening 81 of the first metal mask 80 may have the same diameter as the jig opening 71.

In the above-described embodiment, although the covering jig 70 and the fixing jig 72 are disposed during the jig disposing step S32C, the fixing jig 72 may be omitted.

In the above-described embodiment, although the core portions 7 are inserted into the penetration holes 30 and 31 using the rivet members 9 during the core disposing step S32B, the present invention is not limited to this. For example, core portions 7 which are not assembled on base portions 8 may be used.

In the above-described embodiment, although the filling material filled into the penetration holes 30 and 31 is the paste-like glass frit 6a, the present invention is not limited to this. For example, the filling material may be a conductive paste (for example, silver paste or the like), and the core disposing step S32B may be omitted.

In the above-described embodiment, although the penetration electrode forming step S32 includes the penetration hole forming step S32A where the penetration holes 30 and 31 are formed in the hole forming region R1, instead of this, a recess forming step may be performed where recess portions (holes) are formed in the hole forming region R1 so as to be opened to the outer surface 40a side of the base board wafer 40. In this case, for example, during the polishing step S32I, the inner surface 40b side of the base board wafer 40 may be polished until the core portions 7 are exposed.

In the above-described embodiment, although the bonding film 35 is formed on the lid board wafer 50, contrary to this, the bonding film 35 may be formed on the inner surface 40b of the base board wafer 40. In this case, it is preferable that the bonding film 35 is formed on only the bonding surface of the base board wafer 40 to be bonded to the lid board wafer 50 so that the bonding film 35 does not come into contact with the lead-out electrodes 36 and 37.

In the above-described embodiment, although the piezoelectric vibrator 1 is manufactured by sealing the piezoelectric vibrating reed 4 in the inside of the package 5 while using the package manufacturing method according to the present invention, devices other than the piezoelectric vibrator may be manufactured by sealing an electronic component other than the piezoelectric vibrating reed 4 in the inside of the package 5.

In the above-described embodiment, although the case where the present invention is applied to the two-layered piezoelectric vibrator 1 in which the cavity C is formed between the base board 2 and the lid board 3 was described, the present invention is not limited to this, and the present invention may be applied to a three-layered piezoelectric vibrator in which a piezoelectric board is interposed between a base board and a lid board.

In addition, within a range not deviating from the object of the present invention, constituent elements of the above-described embodiments may be appropriately substituted with well-known constituent elements, and the above-described modified examples may be appropriately combined.

What is claimed is:

1. A method for producing piezoelectric vibrators, comprising:
(a) defining a plurality of first substrates on a first wafer and a plurality of second substrates on a second wafer;
(b) forming a pair of holes in a respective at least some of the first substrates on the first wafer;
(c) placing a cover formed with an opening on the first wafer such that at least some of the holes are visible through the opening;
(d) placing on the cover a mask formed with a window which is at least as larger as the opening of the cover, such that the at least some of the holes visible through the opening are also visible through the window;
(e) applying filler through the opening and the window to fill with the filler at least some of the holes visible through the opening and the window;
(f) removing the first mask and drying the applied filler; and
(g) optionally repeating a process of steps (d), (c) and (f) at least once, wherein a mask used in one of repeated processes has a window larger than a window of a mask used in an immediately preceding process.

2. The method according to claim 1, wherein the window of the mask is larger than the opening of the cover.

3. The method according to claim 1, further comprising, before step (e), placing a conductive member in a respective at least some of the holes.

4. The method according to claim 3, wherein the conductive member is shorter than a depth of the holes and the method further comprises grinding a surface of the first wafer to expose the conducive members.

5. The method according to claim 1, wherein the holes have a bottom.

6. The method according to claim 5, further comprising grinding a surface of the first wafer to make the holes through-holes.

7. The method according to claim 1, wherein placing a cover on the first wafer comprises fixing the first wafer with respect to the cover.

8. The method according to claim 1, further comprising, before step (c), washing the cover to remove any filler left on the cover.

9. The method according to claim 1, wherein the hole has a configuration getting narrower from one end thereof towards the other.

10. The method according to claim 1, further comprising:
layering the first and second wafers such that at least some of the first substrates substantially coincide respectively with at least some of the corresponding second substrates, wherein a piezoelectric vibrating strip is secured in a respective pairs of at least some of coinciding first and second substrates;
hermetically bonding the first and second substrates of at least some of the respective pairs; and
cutting off respective at least some of the hermetically bonded pairs from the first and second wafers.
